(19) United States
(12) Patent Application Publication
(10) Pub. No.: US 2008/0227300 A1
(43) Pub. Date: Sep. 18, 2008

(54) Method for manufacturing semiconductor device

(75) Inventor: Young Sun Hwang, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/987,757

(22) Filed: Dec. 4, 2007

(30) Foreign Application Priority Data
Mar. 16, 2007 (KR) 10-2007-0026143

(51) Int. Cl. H01L 21/467

(52) U.S. Cl. 438/703; 257/E21.486

(57) ABSTRACT

A method of manufacturing a semiconductor device prevents a pattern bridge phenomenon generated by a proximity effect between patterns and a thickness lowering phenomenon of the pattern. As a result, a length of the major axis required in characteristics of the device is secured to improve an electric characteristic and an overlapping margin. A photoresist pattern is formed to have a line/space type, thereby securing a DOF margin in comparison with a photoresist pattern of an island type.

This application is based upon and claims the benefit of priority to Korean Patent Application No. 10-2007-0026143, filed on Mar. 16, 2007, the entire contents of which are incorporated herein by reference.

### TECHNICAL FIELD

The present invention generally relates to a method of manufacturing a semiconductor device, and more specifically, to a method of manufacturing a semiconductor device which prevents a pattern bridge phenomenon generated by a pattern proximity effect and a thickness lowering phenomenon of a major axis edge unit of a photoresist pattern to secure the major axis length required in a characteristic of the device, thereby improving an electric characteristic and an overlapping margin. The method includes forming a photoresist pattern having a line/space type, thereby securing a depth of focus (DOF) in comparison with a photoresist pattern having an island type to improve characteristics of the device.

### BACKGROUND

Due to high integration of semiconductor devices, the whole chip area is increased in proportion to increase of memory capacity, thereby reducing the cell area of a pattern of the semiconductor device.

In order to secure a desired memory capacity, a larger number of patterns should be formed in a limited cell region. As a result, a fine pattern having a reduced critical dimension is required.

In a conventional method of forming a pattern of a semiconductor device, an underlying layer and a hard mask layer are sequentially deposited over a semiconductor substrate.

A photoresist film is coated over the hard mask layer. An exposure and developing process is performed on the photoresist film to form a photoresist pattern having an island type.

The hard mask layer is etched with the photoresist pattern as an etching mask to form a hard mask having an island type.

After the photoresist pattern is removed, the underlying layer is etched with the hard mask as an etching mask to form an underlying layer pattern having an island type.

When a space region between major axes of the underlying layer pattern is formed to be broad, a bridge is not generated. However, a critical dimension of the space region is reduced as the size of the pattern is reduced so that a pattern bridge is generated by a proximity effect between patterns.

The photoresist pattern has a lower thickness toward the major axis than toward a uni-axis. As a result, the edge part of the photoresist pattern has a sharp slope toward the major axis.

When the hard mask layer is etched, the critical dimension of the major axis of the hard mask is patterned by the photoresist pattern smaller than that of the desired pattern.

### SUMMARY

There is provided a method of manufacturing a semiconductor device which prevents a pattern bridge phenomenon and a thickness lowering phenomenon of a photoresist pattern, thereby securing a critical dimension of the photoresist pattern to improve an electric characteristic and an overlapping margin of the device. The method includes forming a hard mask and a photoresist pattern having a line/space type to secure a depth of focus (DOF) margin, thereby improving characteristics of the device.

In one embodiment, a method of manufacturing a semiconductor device comprises: forming a first mask pattern having a line/space type over an underlying layer of a semiconductor substrate; forming a second mask pattern having a line/space type over the underlying layer including the first mask pattern in a direction crossing with the first mask; etching the first mask pattern using the second mask pattern as an etching mask to form a third mask pattern of an island type; and etching the underlying layer using the third mask pattern as an etching mask to form an underlying pattern of an island type.

### BRIEF DESCRIPTION OF THE DRAWINGS

FIGS. 1a through 1e are cross-sectional diagrams illustrating a method of manufacturing a semiconductor device consistent with an embodiment consistent with the invention.

### DETAILED DESCRIPTION

Hereinafter, an embodiment will be described with reference to the accompanying drawings.

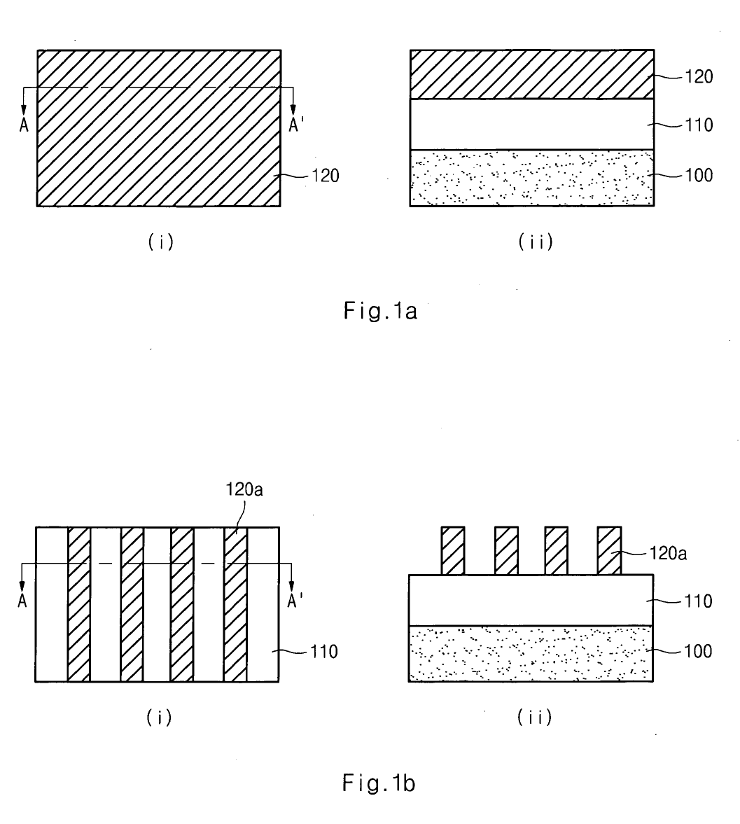

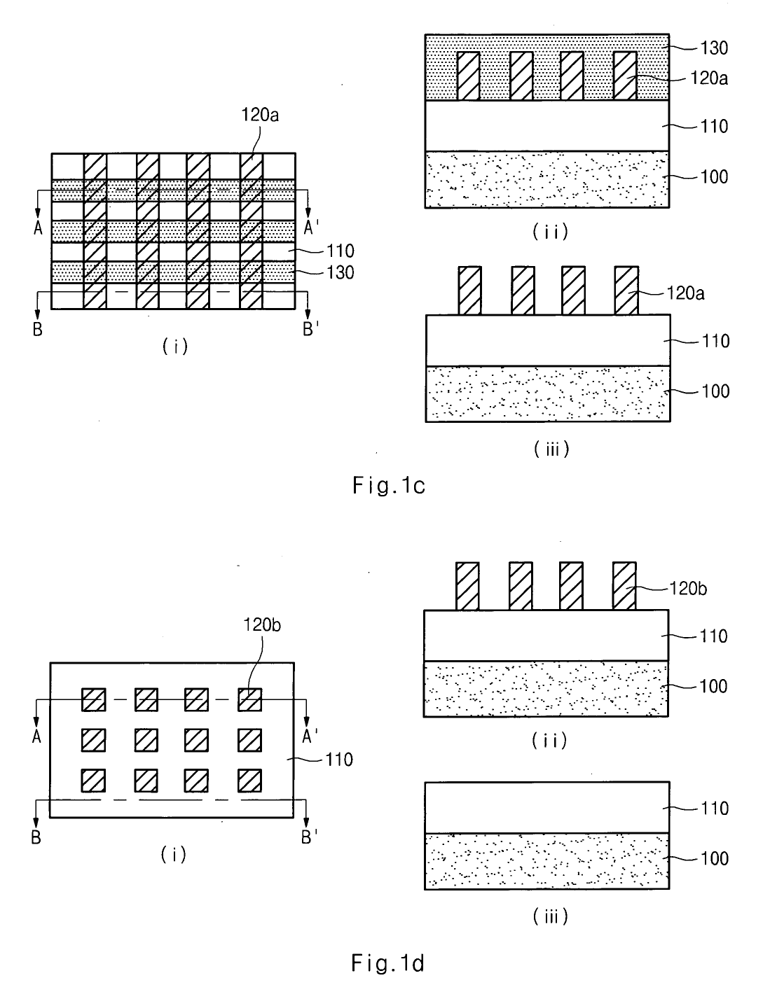

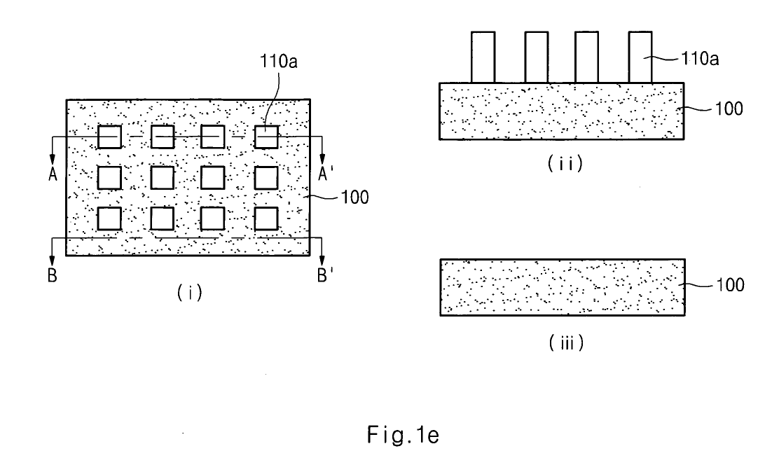

FIGS. 1a through 1e are cross-sectional diagrams illustrating a method of manufacturing a semiconductor device consistent with an embodiment consistent with the invention. (i) shows a plane diagram, (ii) shows a cross-sectional diagram taken along A-A′, and (iii) shows a cross-sectional diagram taken along B-B′.

Referring to FIG. 1a, an underlying layer 110 is formed over a semiconductor substrate 100, and a hard mask layer 120 is formed over the underlying layer 110.

A first photoresist film is coated over the hard mask layer 120. An exposure and developing process is performed to form a first photoresist pattern having a line/space type. The exposure process is performed with a light source selected from I-Line, KrF and ArF.

Referring to FIG. 1b, the hard mask layer 120 is etched with the first photoresist pattern as an etching mask to form a hard mask 120a having a line/space type. A space critical dimension of the hard mask 120a ranges from 80 to 100 nm.

Referring to FIG. 1c, the first photoresist pattern is removed, and a second photoresist film is coated over the resulting structure including the hard mask 120a. An exposure and developing process is performed to form a second photoresist pattern 130. The second photoresist pattern 130 is formed to have a line/space type in a direction crossed with a line pattern of the hard mask 120a. A space critical dimension of the second photoresist pattern 130 ranges from 80 to 100 nm.

The hard masks 120a are alternately exposed by the second photoresist pattern 130. The hard mask 120a has an island type.

Referring to FIG. 1d, the hard mask 120a is etched with the second photoresist pattern 130 as an etching mask to form a hard mask 120b having an island type.

Referring to FIG. 1e, the second photoresist pattern 130 is removed. The underlying layer 110 is etched with the hard mask 120b as an etching mask to form an underlying layer pattern having an island type. The hard mask 120b is removed.

The process of forming a pattern having an island type may be applied to all semiconductor devices including a main cell and a peripheral circuits.

As described above, according to an embodiment consistent with the application, a hard mask having a line/space type is formed, and a photoresist pattern having a line/space type is formed in a direction crossed with the hard mask. The hard mask is etched with the photoresist pattern as an etching mask to form a hard mask having an island type, thereby preventing a pattern bridge phenomenon and a thickness lowering phenomenon of the photoresist pattern to secure a major axis critical dimension of the pattern and to improve an electric characteristic and an overlapping margin of the device.

The hard mask and the photoresist pattern having a line/space type are formed alternately to secure a depth of focus (DOF) margin, thereby improving characteristics of the device.

The above embodiments of the present invention are illustrative and not limiting. It will be apparent to those skilled in the art that various modifications and variations may be made in the present invention without departing from the spirit and scope consistent with the invention as defined by the appended claims.

What is claimed is:

1. A method of manufacturing a semiconductor device, the method comprising:
forming a first mask pattern having a line/space type over an underlying layer of a semiconductor substrate;
forming a second mask pattern having a line/space type over the underlying layer including the first mask pattern in a direction crossing with the first mask;
etching the first mask pattern using the second mask pattern as an etching mask to form a third mask pattern of an island type; and
etching the underlying layer using the third mask pattern as an etching mask to form an underlying pattern of an island type.

2. The method according to claim 1, wherein the second mask pattern is formed by employing a light source selected from the group consisting of I-Line, KrF and ArF.

3. The method according to claim 1, wherein a space critical dimension each of the first mask pattern, the second mask pattern and the third mask pattern ranges from 80 to 100 nm, respectively.

4. The method according to claim 1, wherein the forming-a-first-mask-pattern step includes:
depositing a mask layer over the underlying layer;
coating a photoresist film over the mask layer;
performing an exposure and developing process on the photoresist film to form a photoresist pattern of a line/space type; and
etching the mask layer using the photoresist pattern of a line/space type as an etching mask.

5. The method according to claim 1, wherein the first mask pattern and the third mask pattern are hard masks, respectively.

6. The method according to claim 1, wherein the second mask pattern is a photoresist pattern.
